(19) United States
(12) Patent Application Publication
(10) Pub. No.: US 2014/0227885 A1
(43) Pub. Date: Aug. 14, 2014

(54) METHOD FOR THE CONDITIONING OF FLAT OBJECTS

(71) Applicant: Jens Moecke, St. Antoni (CH)

(72) Inventor: Jens Moecke, St. Antoni (CH)

(73) Assignee: RENA GMBH, Gütenbach (DE)

(21) Appl. No.: 14/233,102

(22) PCT Filed: Jun. 1, 2012
(86) PCT No.: PCT/EP2012/060371

§ 371 Date: Jan. 15, 2014

(30) Foreign Application Priority Data
Aug. 18, 2011 (DE) 102011110592.5

(51) Int. Cl. H01L 21/02

(52) U.S. Cl. CPC H01L 21/02019
USPC 438/753

(57) ABSTRACT

The invention relates to a method for the conditioning of flat objects such as silicon substrates.

The objects, obtained by sawing from a block form a comb like structure by being fixed with one edge to a plate shaped fixation apparatus, are conditioned by conventional rinsing, separating and wet chemical treatment, wherein the treatment takes place before the separation of the sawed substrates from the fixation apparatus.

An apparatus which is suitable for carrying out the method has two regions arranged parallel to the apparatus longitudinal axis (L) and above one another, wherein the upper region is configured as an adapter region (1). The lower region is formed as a holding region (2) which comprises a part, provided as a channel (11), of a circumferentially closed or closable channel system which can be supplied with liquid by means of closable supply openings (5). The bottom of this channel (11) is opened in a slot-like fashion during the sawing of the substrate block so as to provide passage openings (15) for the treatment liquid, and it is subdivided into a plurality of sections (11A, 11B) along the apparatus longitudinal axis (L).

### INTRODUCTION

The invention relates to a method for the conditioning of flat objects. In particular, the invention relates to a method wherein the flat objects are silicon substrates, and the conditioning relates to a treatment of these substrates after the sawing from an ingot, but before the separation of the substrates.

### STATE OF THE ART AND DISADVANTAGES

In order to make available for further processing flat objects such as in particular silicon substrates (subsequently called substrates in short) which are sawed from a block, such as in particular a silicon ingot, it is necessary in most cases to remove the contaminations (slurry) which occur during sawing from the interspaces of the substrates which initially adhere with one edge to a plate shaped fixation apparatus (sawing plate, carrier plate). Various apparatuses are known for this purpose, such as e.g. from document DE 10 2006 059 810, PCT/EP2007/010735, or from PCT/EP2008/010460. These apparatuses allow a showering of the not yet separated substrate stack inside an according basin, wherein showering bars or the same which are located at the sides of the stack are being used. Document DE 102 20 468 A1 as well discloses a comparable cleaning method. All these apparatuses and methods have in common that the cleaning takes place in a separate cleaning apparatus, after the sawing.

Another solution is disclosed by German patent application DE 10 2010 052 635 in which the rinsing takes place through boreholes which are inserted in the carrier plate and which are fed by channels running inside the carrier plate. This apparatus can also already be used in the sphere of the wafer saw for cleaning the substrate interspaces. A similar solution shows the method as disclosed in DE 102 25 851 A1, and the apparatus as disclosed in DE 10 2010 022 289 A1.

After sawing, the mechanically brittle materials such as e.g. silicon are particularly prone to breakage. As is known, in particular, sharp edges serve as a source of brittle fractures.

Therefore, an etching, also called saw damage etching, often takes place in an according etching device after the separating. This treatment serves for the leveling of noses or the rounding of grooves, respectively, which developed during sawing.

Up to date, a so-called slurry saw has been used for the sawing of silicon in most cases. It stands out in that the saw wire develops its sawing effect only by means of the liquid mixture which contains, amongst others, the cutting particles such as silicon carbide. For this method, the sawing damages are yet clearly measurable; but they are however still in a range which allows for the detaching of the sawed substrates and a subsequent transport into the etching basin without the risk of fracture becoming too big. Just lately, the slurry sawing is replaced by sawing with a wire with the cutting particles firmly attached thereto (FASW, fixed abrasive sawing wire). A diamond coated wire can be mentioned here as an example (diamond sawing). However, this method which is in principle more cost-effective entails a more severe saw damage. Thus, the risk of breakage of the substrates also increases for a transport immediately following the sawing.

Furthermore, the required space, particularly the length, of a typical treatment line which consists of sequentially arranged modules (saw, cleaning apparatus, etching bath, optionally drying and separating) is large.

### OBJECT OF THE INVENTION AND SOLUTION

It is therefore object of the invention to provide a method that conditions the substrates after the sawing, but before the separating, sufficiently enough that the separating and transport process of the substrates which immediately follows the sawing can occur without, or at least with no increased, risk of breakage in comparison with the risk of breakage known from the art. Furthermore, the method shall be suitable of reducing the required space of a facility which is suitable for carrying out the conditioning.

The object is solved by the method according to claim 1. Preferred embodiments are contained in the dependent claims, the subsequent description, as well as the figures.

### DESCRIPTION

Firstly, in the following, a detailed description of the method according of the invention is given. It is followed by the description of an apparatus which is particularly preferred with regard to the method according to the invention. As far as the term “substrate” is being used, it stands as a substitute for “flat object”.

The method according to the invention serves for the conditioning of fragile flat objects such as in particular silicon substrates produced by sawing from a block. The term conditioning does not exclude that the flat object will possibly be subjected to further process steps which however form not part of the invention. According to the invention, the flat objects or substrates are fixed with one edge to a plate shaped fixation apparatus, thus forming a comb like structure. For fixation, a glue is typically used; however, fixation by clamping is also possible. Conditioning typically comprises conventional rinsing/cleaning, separating and wet chemical treatment (subsequently called “treatment” in short).

For rinsing, e.g. water, for cleaning, a surfactant-containing or even acetous solution can be used. Presently, the term “treating” means liquid treatment of any kind. Separating is the process of detaching the flat objects or substrates from the fixation apparatus, but also the breaking off of individual objects or substrates from the comb like structure.

According to the invention, the wet chemical treatment takes place before the separation of the sawed objects or substrates from the fixation apparatus.

It is ensured by the treatment of the substrates before detaching and separating them that the initially high fragility of the substrates significantly decreases, such that the risk of damage during the subsequent separating is significantly reduced. In this way, even particularly thin substrates can be sawed from the ingot by means of a method which results in an comparably high sawing damage, without the probability of substrate breakage being unacceptably high at the time of separating.

Presently, the term “treating” means any kind of wet chemical treatment for the modification of the substrate surface. In particular, the term relates to a wet chemical treatment such as etching or structuring with a surface-affecting liquid by means of which amounts of the substrate material are removed, as well as the doping and the electrochemical treating (e.g. anodizing) of the substrate surface.

It is further preferred that an additional rinsing or cleaning step and/or a step for stopping the wet chemical treatment is carried out after the treatment, but before the separating of the objects or substrates. Such a step is typically necessary in order to end the etching process. It is therefore preferred that also such a step is carried out still before the separating.

According to a further, preferred embodiment, the injection of at least one of the liquids, i.e. the cleaning, rinsing or etching liquid, which are used in the context of the method, into the interspaces of the comb like structure of the sawed, non-separated substrates takes place straight through the fixation apparatus. An apparatus which is suitable for this will be described later on. It is however clear that this apparatus has according openings through which the liquid(s) can be injected into the spaces between the substrates of the comb like structure.

It is particularly preferred that all of said liquids are injected straight through the fixation apparatus into the interspaces of the substrates. In this manner, the aforementioned advantages of gentle and timesaving treatment can be combined with the particularly effective cleaning and etching effect of such an apparatus.

As already indicated, the block is preferably a silicon ingot from which silicon substrates are sawed. However, the invention is not limited to this material, but its advantages become evident also for the sawing of e.g. ceramic, glass-like or other materials or material composites which tend to brittle fractures.

A typical etchant which is used for the treatment comprises KOH, NaOH, HF, HNO₃, H₂SO₄, H₃PO₄ or C₂H₄O₂, although naturally, the invention can also be executed with other etching as well as any rinsing or cleaning liquids as well as water.

According to another embodiment, the steps of (initial) rinsing and/or treatment take place within the sawing device in which the ingot was sawed. In this manner, the length of an according continuous line can be significantly decreased, and the risk of damaging the substrates due to repositioning processes can be reduced. Furthermore, a time advantage results from omission of the repositioning process.

According to a preferred embodiment, the steps of (initial) rinsing and/or treatment take place not within a sawing device, but outside of the same, and in separately provided rinsing or treatment devices, respectively.

The usage of such devices has the advantage that the sawing device must not be resistant against the liquid of the etchant which is typically corrosive for metals as well. This would involve accordingly high efforts, since conventional sawing devices have a multitude of metallic components which would come in contact with the possibly different liquids. Furthermore, the period of time during which an ingot is treated in a saw is significantly longer than the period during which the subsequently sawed, but not yet separated comb like structure stays in the separate etching or cleaning device. Thus, one single, separate etching or cleaning device can serve several sawing devices which are arranged upstream to it.

Devices which are particularly suitable for the rinsing or cleaning process are disclosed in documents EP 1 935 514, PCT/EP2007/010735, EP 2 102 896 and EP 08860195, all originating from the present applicant.

According to a particularly preferred embodiment, the steps of (initial) rinsing and/or treatment take place outside of a sawing device in a combined rinsing and treatment device. In this manner, a repositioning of the substrate block from e.g. an etching to a cleaning device, and thus the resulting time loss and the risk of substrate damages, are avoided. The aforementioned devices which originate from the applicant can preferably also be used in principle as such combined rinsing and treatment devices. It is clear that the disclosed devices must be resistant against corrosive liquids, and that they must have suitable liquid inlets which allow for the supply of rinsing as well as treatment liquid in direction of the substrate block within the device. Since amongst others, a cleaning device just serves for the rinsing off of treatment such as e.g. etching liquid, consequentially, it is typically resistant against such liquid. If necessary, the provision of supplies for several liquids represents only a minor constructive change or addition.

It is further clear that all these mentioned apparatuses interact particularly preferably with the aforementioned and subsequently described “fixation-cleaning apparatus for the sectioned cleaning of sawed wafers”, and particularly independent of whether the rinsing and treatment takes place in a combined rinsing and treatment device, or in separate rinsing and cleaning devices.

In the following, an apparatus is described which is particularly suitable for carrying out the method according to the invention.

This apparatus can be defined as “fixation-cleaning apparatus for the sectioned cleaning of sawed wafers”. The term “wafer” is synonymous with the terms “flat object” and “substrate”.

Such an apparatus for holding a substrate block to be sawed and for treating the interspaces formed by sawing the substrate block has two regions arranged parallel to the apparatus longitudinal axis and above one another, the upper region being configured as an adapter region by means of which the apparatus can be connected to a machine instrument such as e.g. a sawing device. The lower region is formed as a holding region which comprises a part, provided as a channel, of a circumferentially closed or closable channel system which can be supplied by means of closable supply openings with liquid that is in particular a rinsing, cleaning, or etching liquid. The bottom of this channel is opened in a slot-like fashion during the sawing of the substrate block so as to provide passage openings for the treatment liquid. Furthermore, the channel is subdivided into a plurality of sections along the apparatus longitudinal axis.

Preferably, these sections of the channel along the apparatus longitudinal axis can be supplied independently of one another with treatment liquid.

Preferably, the channel is subdivided by a plurality of structurally separate channels which can be supplied independently of one another.

Particularly preferred, the channel is subdivided by a plurality of barriers fitted removably in the channel. A channel which initially runs nearly completely along the apparatus can accordingly be separated with these barriers. The positions of the barriers can be determined flexibly according to requirements when assembling the device.

The closable supply openings are preferably arranged on the upper flat side or at the circumferential side of the adapter region.

Particularly preferred, the holding region is designed as a fixation plate and the adapter region is designed as an adapter plate, and the two plates are connected releasably to one another.

As material of the holding region, glass, plastic, epoxide, ceramic, metal and mixtures thereof are possible.

By using this apparatus, a particularly preferred method for its operation can be described as follows:
Supplying the channel system with a first treatment liquid by means of the closable supply openings arranged in the upper region;
Provision of the first treatment liquid in the channel of the holding region;
Treating the interspaces with the first treatment liquid which passes through the slot-like passage openings which have been formed in the bottom of the channel when sawing the substrate block;
Supplying the channel system with a further treatment liquid by means of the closable supply openings arranged in the upper region
Providing the further treatment liquid in the channel of the holding region;
Treating the interspaces with the further treatment liquid which passes through the slot-like passage openings which have been formed in the bottom of the channel when sawing the substrate block;

Particularly preferred, the first treatment liquid is a cleaning or rinsing liquid, and the second treatment liquid is an etchant.

Particularly preferred, the respective supply of the channel system and the rinsing, cleaning or treatment of the interspaces takes place zonally as seen in the device longitudinal axis. In other words, a certain section of the apparatus which preferably is a longitudinal section can individually be supplied with treatment liquid, independently of one or several other sections. Amongst others, this results in the advantage that the loss of treatment liquid can further be reduced, as long as such a substrate block is to be rinsed or treated which does not extend along the entire length of the apparatus.

Particularly preferred, the treatment is carried out partially or entirely in the working region of a wafer saw.

It is clear that optionally, additional steps such as the aforementioned stopping of the treatment process can follow that are carried out by means of the described apparatus, and particularly preferred in the working region of a wafers saw.

The invention provides a method that conditions the substrates after the sawing, but before the separating, sufficiently enough that the separating and transport process of the substrates which immediately follows the sawing can occur without, or at least with no increased, risk of breakage in comparison with the risk of breakage known from the art. Furthermore, the method is suitable of reducing the required space of a facility which is suitable for carrying out the conditioning.

### DESCRIPTION OF FIGURES

FIG. 1 shows an external view of a preferred embodiment of the apparatus according to the invention.

FIG. 2 shows a sectional view of the device according to FIG. 1.

FIG. 3 shows a further sectional view of the apparatus according to FIGS. 1 and 2 with a substrate block.

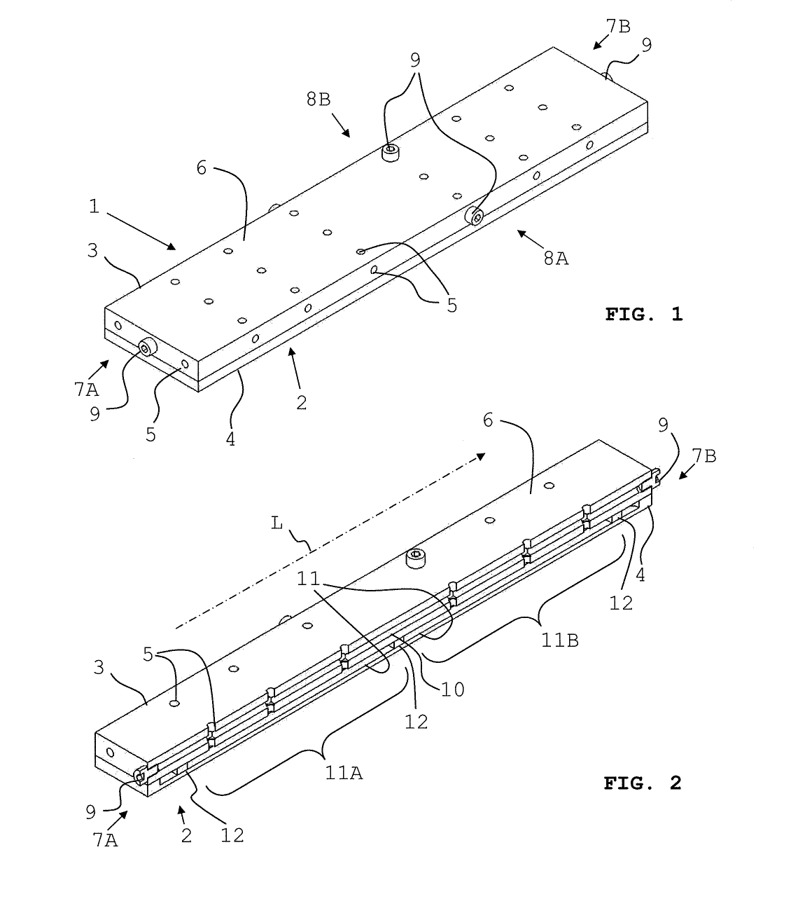

In FIG. 1, a preferred embodiment of the apparatus which is preferably to be used is depicted in perspective view. The device comprises an upper region used as an adapter region 1, and a lower region used as a holding region 2 for one or more substrate blocks (not shown). Here, the adapter region 1 is provided as a separate component, depicted at the top of the image, namely as the adapter plate 3, and the holding region 2 is provided likewise as a separate component, namely as the fixation plate 4. The figure furthermore shows a multitude of supply openings 5 (only some of which are provided with references). The supply openings 5 in the present case are arranged on the upper flat side 6, on the front and rear end sides 7A, 7B, and on the right and left sides 8A, 8B of the device. All the supply openings 5 are located in the adapter region 1, or in the adapter plate 3. Some of the supply openings 5 are closed by means of closure screws 9.

FIG. 2 shows a sectional view, extending along the device longitudinal axis L (dot-and-dash arrow), of the apparatus as previously described. The function of the closure screws 9 arranged on the end sides 7A, 7B can be seen clearly. They close a channel 10 which is arranged in the adapter plate 3, the channel extending through the entire apparatus, and being part of a branched channel system. The latter can be supplied with treatment liquid (not shown) through the supply openings 5 (some of which are without references in FIG. 2). The depicted embodiment is provided merely for illustration with a few closure screws 9; in the normal case, most of the closable supply openings 5 are in fact closed, so that the treatment liquid cannot emerge at an undesired position.

As can be seen, according to the depicted embodiment, part of the channel system is also provided in the form of a channel 11 in the holding region 2, or in the fixation plate 4, respectively. There, in the present case, it can be supplied by means of the channel 10 and by means of supply openings 5, which are located in the upper flat side 6 of the adapter plate 3. This part of the channel system comprises two sections 11A, 11B. Depending on the position of the closure screws 9, the latter can be supplied separately from one another. In order to form these two sections 11A, 11B, liquid-blocking or liquid-disrupting barriers 12 fitted removably in the channel system are provided in the corresponding part of the channel system (channel 11). With these, it is correspondingly possible to subdivide the channel 11 which initially extends through almost all of the device. The positions of the barriers 11 can be determined flexibly according to requirements when assembling the device.

According to a not depicted embodiment, the apparatus comprises several channels that run at least within the fixation plate and which can be supplied separately from each other, e.g. with different treatment liquids. Preferably, these channels run in parallel. They are commonly opened in a slot-like fashion during the sawing of the substrate block so as to provide passage openings for the treatment liquid. It is clear that channels of this embodiment can also be built in segments, and that the respective sections can be supplied independently of each other.

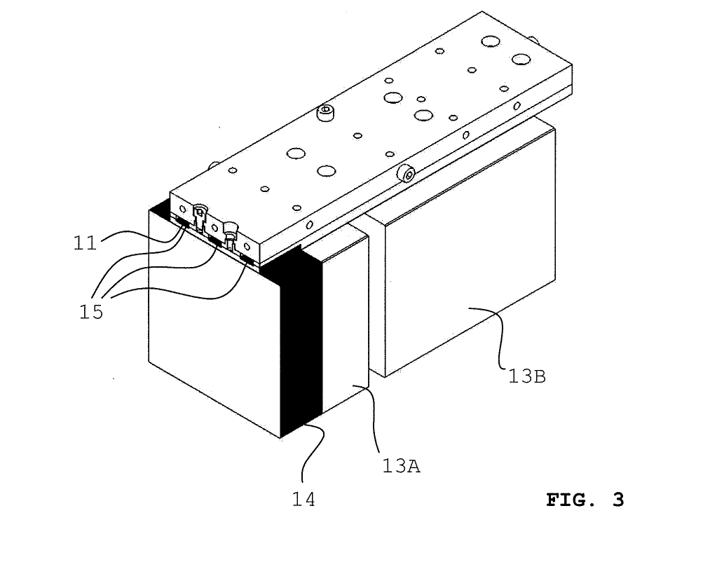

FIG. 3 shows a frontal sectional view of the apparatus according to FIGS. 1 and 2. Two substrate blocks 13A, 13B are furthermore represented, which are arranged suspended from the apparatus. The rear substrate block 13B has not yet been sawed, while the front substrate block 13A has already been partially sawed into individual substrates 14 (region with black side face). As can be seen in FIG. 3, there are now passage openings 15 in the channel 11. The passage openings 15 have been produced when sawing the substrate block 13A into the substrates 14 by means of a sawing wire or another sawing means (not shown). If treatment liquid (not shown) is applied to the channel system by supplying it by means of the supply openings (not provided with references), the treatment liquid emerges from the passage openings 15. From there, it flows into the region of the interspaces of the substrates 14, where it, according to the type of liquid, flushes out any slurry which may be present (rinsing function), cleans the substrate surface (cleaning function), chemically attacks (etching function) or modifies the same (doping function). Since the interspaces are open toward the sides and downward, the treatment liquid, optionally loaded with remnants to be discharged, can flow away unimpeded. According to the position of the barriers that form the sections (not shown), the channel 11 can be divided such that a first section 11A can supply the substrate block depicted in the left of the picture, and a second section 11B can supply the substrate block depicted in the right of the picture with liquid (channel and sections not visible).

### LIST OF REFERENCES

1 adapter region
2 holding region
3 adapter plate
4 fixation plate
5 supply openings
6 upper flat side
7A front end side
7B rear end side
8A right side
8B left side
9 closure screw
10 channel
11 channel
11A first section
11B second section
12 barrier
13A substrate block
13B substrate block
14 substrate
15 passage openings
L device longitudinal axis

1. Method for conditioning silicon substrates produced by sawing from a block, the substrates forming a comb like structure by being fixed with one edge to a plate shaped fixation apparatus, by conventional rinsing, separating and wet chemical treatment, wherein the treatment modifies the substrate surface by way of etching or structuring and takes place before the separating of sawed substrates from the fixation apparatus.

2. Method according to claim 1, wherein an additional rinsing step and/or a step for stopping the treatment is carried out after the treatment, but before the separating of the substrates.

3. Method according to claim 1, wherein injection of at least one of the liquids which are used in the context of the method into the interspaces of the comb like structure takes place straight through the fixation apparatus.

4. Method according to claim 3, wherein all of the liquids which are used in the context of the method are injected straight through the fixation apparatus into the interspaces.

5. Method according to claim 1, wherein an etching liquid which comprises a member selected from the group consisting of KOH, NaOH, HF, HNO₃, H₂SO₄, H₃PO₄, and C₂H₄O₂ is used for the treatment.

6. Method according to claim 1, wherein the steps of rinsing and/or treatment take place within a sawing device.

7. Method according to claim 1, wherein the steps of rinsing and/or treatment take place outside of a sawing device, in separately provided devices.

8. Method according to claim 1, wherein the steps of rinsing and/or treatment take place outside of a sawing device in a combined rinsing and treatment device.
